(19) United States
(12) Patent Application Publication
(10) Pub. No.: US 2014/0332583 A1
(43) Pub. Date: Nov. 13, 2014

(54) WIRE BONDING APPARATUS

(71) Applicant: SHINKAWA LTD., Tokyo (JP)

(72) Inventor: Toru MAEDA, Tokyo (JP)

(73) Assignee: SHINKAWA LTD., Tokyo (JP)

(21) Appl. No.: 14/339,632

(22) Filed: Jul. 24, 2014

Related U.S. Application Data
(63) Continuation of application No. PCT/JP2012/072783, filed on Sep. 6, 2012.

(30) Foreign Application Priority Data
Feb. 7, 2012 (JP) 2012-023722

(51) Int. Cl. H01L 23/00

(52) U.S. Cl. CPC H01L 24/78; H01L 2224/7801; H01L 2224/78611
USPC 228/4.5

(57) ABSTRACT

Provided is a wire bonding apparatus including: a base (11); a bonding head (13) configured to move a capillary (15) in X, Y, and Z directions with respect to the base (11); and a wire-cleaning plasma unit (30). The wire-cleaning plasma unit (30) includes: hollow casings (31a), (31b) in which an inert gas is introduced so that an internal pressure is higher than an atmospheric pressure; holes (33a), (33b) respectively provided in the casings (31a), (31b) so that the wire (21) is inserted therebetween; and electrodes for plasma respectively disposed within the casings (31a), (31b) around circumferences of the holes (33a), (33b). The wire (21) is cleaned by having the wire (21) be inserted into plasma generated within the casings (31a), (31b) in a state in which air is not contained. With this, a surface of the wire used for wire bonding can be effectively cleaned.

### TECHNICAL FIELD

The present invention relates to a structure of a wire bonding apparatus having a wire cleaning function.

### BACKGROUND ART

Wire bonding apparatuses for connecting an electrode of a chip and an electrode of a substrate with a metallic wire have been widely used. Such wire bonding apparatuses have a problem that oxidization of a surface of the wire for connection may often cause deterioration in bond properties with an electrode, and thus in bond strength and electric properties. Therefore, many of such wire bonding apparatuses perform connection between a wire and an electrode using gold wires, whose surface is not oxidized.

However, while gold wires are superior in bond properties, they are expensive and their electric properties are low as compared to copper. Accordingly, in recent years, wire bonding apparatuses using copper wires have been proposed. In order to ensure favorable connection, it is necessary for the wire bonding apparatuses using copper wires to perform bonding to an electrode while maintaining a surface of copper clean. Therefore, there is proposed a method of, before performing bonding, cleaning a surface of a copper wire by irradiating plasma to remove organic impurities attached to the wire surface, blowing a reducing or noble gas to the wire to suppress oxidation of the surface of the wire, and then feeding the wire with a cleaned surface to a bonding tool (see PTL 1, for example).

### CITATION LIST

### Patent Literature

PTL 1: Japanese Unexamined Patent Application Publication (Translation of PCT Application) No. 2008-535251

### SUMMARY OF INVENTION

### Technical Problem

Incidentally, when attempting to generate plasma in an atmospheric pressure, an application of a high-frequency alternating voltage between electrodes is often employed. In this case, it often happens that as the temperature of the generated plasma becomes high, the temperature of a wire irradiated by plasma also becomes high, and a surface of the wire is oxidized while cooling the wire. In contrast, if plasma is generated in an atmosphere depressurized below the atmospheric pressure, it is possible to generate low-temperature plasma at a low voltage. Thus, PTL 1 proposes a method of reducing heating up of a wire due to plasma irradiation by generating low-temperature plasma in a chamber depressurized below the atmospheric pressure and irradiating the wire by the generated plasma.

Whereas, a small amount of air remains in the chamber depressurized below the atmospheric pressure as described in PTL 1, and the remaining air contains oxygen. Accordingly, the plasma generated in the chamber depressurized below the atmospheric pressure as described in PTL 1 is oxidizing plasma, and oxidizes the wire surface at the same time as removal of organic impurities from the wire surface. Therefore, it is necessary for the conventional technique described in PTL 1 to suppress oxidation of the wire surface by providing a compensating device that blows a reducing gas or a noble gas against the wire surface after cleaning the wire by plasma.

However, while it is possible to cool the wire by blowing a reducing gas or a noble gas against the wire oxidized by irradiation of oxidizing plasma, it is difficult to restore a non-oxidized state of the wire surface once oxidized or to remove an oxidized film deposited on the surface. Thus, there is a case in which bonding is ultimately performed using a wire whose surface is oxidized, resulting in insufficient bond properties between the wire and an electrode. This problem is in particular noticeable for copper wires, whose surface is susceptible to oxidation.

An object of the present invention is to provide a wire bonding apparatus capable of effectively cleaning a surface of a wire used for bonding.

### Solution to Problem

A wire bonding apparatus according to the present invention is provided with: a base body; a bonding head configured to move a bonding tool in X, Y, and Z directions with respect to the base body; a wire spool attached to the base body, and configured to feed a wire to the bonding tool; and a wire-cleaning plasma unit disposed between the wire spool and the bonding tool, wherein the wire-cleaning plasma unit includes: hollow casings in which an inert gas is introduced, so that an internal pressure is higher than an atmospheric pressure; holes respectively provided in walls of the casings, and face against each other so that the wire is inserted therebetween; and electrodes respectively disposed within the walls of the casings around circumferences of the holes, so as to face against each other the holes, and the wire is cleaned by applying current to the electrodes and having the wire be inserted into plasma in a space between the electrodes within the casings generated in a state in which air is not contained.

It is preferable that the wire bonding apparatus according to the present invention be configured such that the wire-cleaning plasma unit is attached to the bonding head; such that there are provided at least two wire-feed guides attached to the base body, and configured to guide the wire fed from the wire spool in a linear direction, and the wire-cleaning plasma unit is attached to the base body between the wire-feed guides; or such that the casings respectively include pipes on outer surfaces of the walls, each pipe being communicated with a corresponding one of the holes and allowing the wire to be inserted therethrough.

A wire bonding apparatus according to the present invention is provided with: a base body; a bonding head configured to move a bonding tool in X, Y, and Z directions with respect to the base body; a wire spool attached to the base body, and configured to feed a wire to the bonding tool; at least two wire-feed guides attached to the base body, and configured to guide the wire fed from the wire spool in a linear direction; and a cleaning plasma unit configured to blow plasma jet for cleaning to the wire between the wire-feed guides.

It is preferable that the wire bonding apparatus according to the present invention be configured such that a reducing plasma unit disposed on the side of the bonding tool from the cleaning plasma unit, and configured to further blow plasma for reducing to the wire between the wire-feed guides after the plasma for cleaning has been blown.

A wire bonding apparatus according to the present invention is provided with: a base body; a bonding head configured to move a bonding tool in X, Y, and Z directions with respect to the base body; a wire spool attached to the base body, and configured to feed a wire to the bonding tool; and a cleaning plasma unit attached to the bonding head, and configured to blow plasma jet for cleaning to the wire.

It is preferable that the wire bonding apparatus according to the present invention be configured such that a reducing plasma unit attached to the bonding head on the side of the bonding tool from the cleaning plasma unit, and configured to further blow plasma for reducing to the wire after the plasma for cleaning has been blown.

### Advantageous Effects of Invention

A wire bonding apparatus according to the present invention provides an effect of effectively cleaning a surface of a wire used for bonding.

### BRIEF DESCRIPTION OF DRAWINGS

FIG. 1 is an illustrative view illustrating a configuration of a wire bonding apparatus according to an embodiment of the present invention.

FIG. 2 is a perspective view illustrating an external appearance of a wire-cleaning plasma unit of the wire bonding apparatus according to the embodiment of the present invention.

FIG. 3 is a perspective view illustrating an internal structure of the wire-cleaning plasma unit of the wire bonding apparatus according to the embodiment of the present invention.

FIG. 4 is a perspective-sectional view illustrating the internal structure of the wire-cleaning plasma unit of the wire bonding apparatus according to the embodiment of the present invention.

FIG. 5 is an illustrative view illustrating an operation of the wire-cleaning plasma unit of the wire bonding apparatus according to the embodiment of the present invention.

FIG. 6 is a perspective view illustrating an external appearance of a different wire-cleaning plasma unit of the wire bonding apparatus according to the embodiment of the present invention.

FIG. 7 is an illustrative view illustrating an operation of the different wire-cleaning plasma unit of the wire bonding apparatus according to the embodiment of the present invention.

FIG. 8 is an illustrative view illustrating a configuration of a wire bonding apparatus according to another embodiment of the present invention.

FIG. 9 is an illustrative view illustrating a configuration of a wire bonding apparatus according to yet another embodiment of the present invention.

FIG. 10 is an illustrative view illustrating a configuration of a wire-cleaning plasma unit of the wire bonding apparatus according to the yet another embodiment of the present invention.

FIG. 11 is an illustrative view illustrating a configuration of a wire bonding apparatus according to further another embodiment of the present invention.

### DESCRIPTION OF EMBODIMENTS

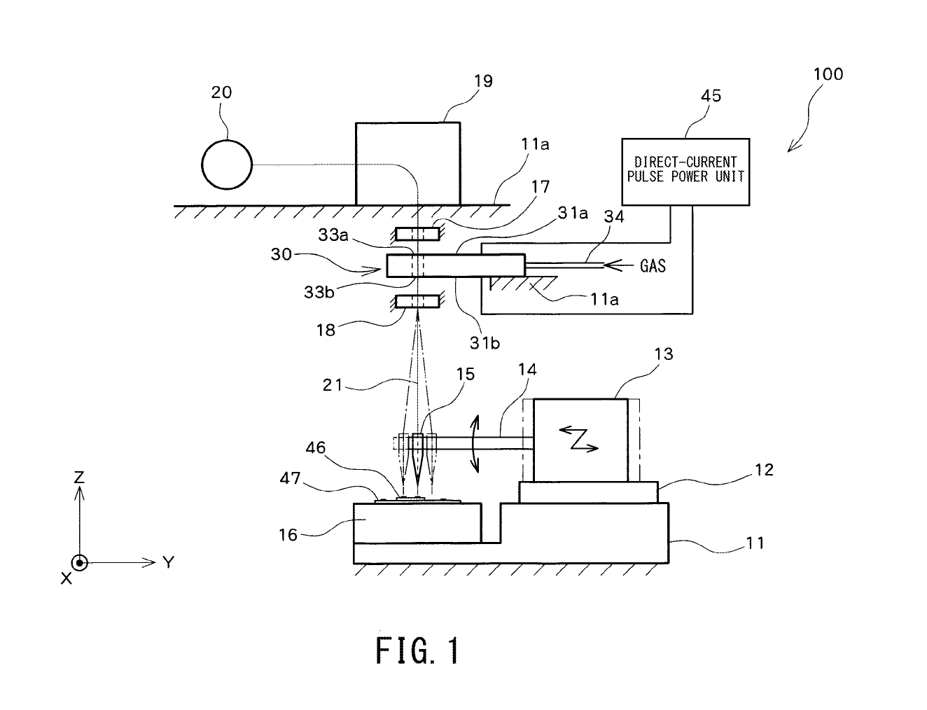

Hereinafter, an embodiment of the present invention will be described with reference to the drawings. As illustrated in FIG. 1, a wire bonding apparatus 100 according to the embodiment includes a base 11 as a base body, an XY table 12 that is provided on the base 11 and whose upper surface moves in X and Y directions, a bonding head 13 provided on the XY table 12, and a bonding arm 14 that causes a capillary 15 as a bonding tool provided at a tip of the arm to move in a Z direction by a Z-direction drive mechanism provided within the bonding head 13. In other words, the bonding head 13 is able to move the capillary 15 in the X, Y, and Z directions by the XY table 12 and by moving the bonding arm 14 in the Z direction by the Z-direction drive mechanism provided inside. Further, the base 11 of the wire bonding apparatus 100 is provided with a bonding stage 16 for suctioning and fixing a substrate 47 to which semiconductor dies 46 used in wire bonding are attached. Note that, in FIG. 1, the Z direction corresponds to a vertical direction of the wire bonding apparatus 100, the Y direction corresponds to a direction from the bonding stage 16 toward the bonding head 13, and the X direction corresponds to a direction perpendicular to an YZ plane.

To an upper frame 11a fixed to the base 11, a wire spool 20 for feeding a wire 21 to the capillary 15, and an air guide 19 for changing a feeding direction of the wire 21 fed from the wire spool 20 into the Z direction are attached. The upper frame 11a is also provided with two wire-feed guides 17 and 18 that guide the direction of the wire 21 that has been changed by the air guide 19 into the Z direction linearly in the Z direction. Between the two wire-feed guides 17 and 18, a wire-cleaning plasma unit 30 for cleaning a surface of the wire 21 is provided. As illustrated in FIG. 1, the wire 21 is inserted into the wire-cleaning plasma unit 30 so as to penetrate through holes 33a and 33b provided in the wire-cleaning plasma unit 30. The wire-cleaning plasma unit 30 is attached to the upper frame 11a that is fixed to the base 11. To the wire-cleaning plasma unit 30, a gas inlet tube 34 for generating plasma for cleaning and a direct-current pulse power unit 45 for supplying direct-current pulse power supply for generating plasma are connected.

While the wire 21 fed from the wire spool 20 hardly moves either in the X or Y direction when positioned between the two wire-feed guides 17 and 18, it moves in the X and Y directions as indicated by an alternate long and short dash line shown in FIG. 1, when positioned between the wire-feed guide 18 on the lower side and the capillary 15, in association with movement of the bonding head 13 and the capillary 15.

The wire 21 is inserted through the capillary 15 and bonded onto an electrode of the semiconductor die 46 or the substrate 47 with a tip of the capillary 15.

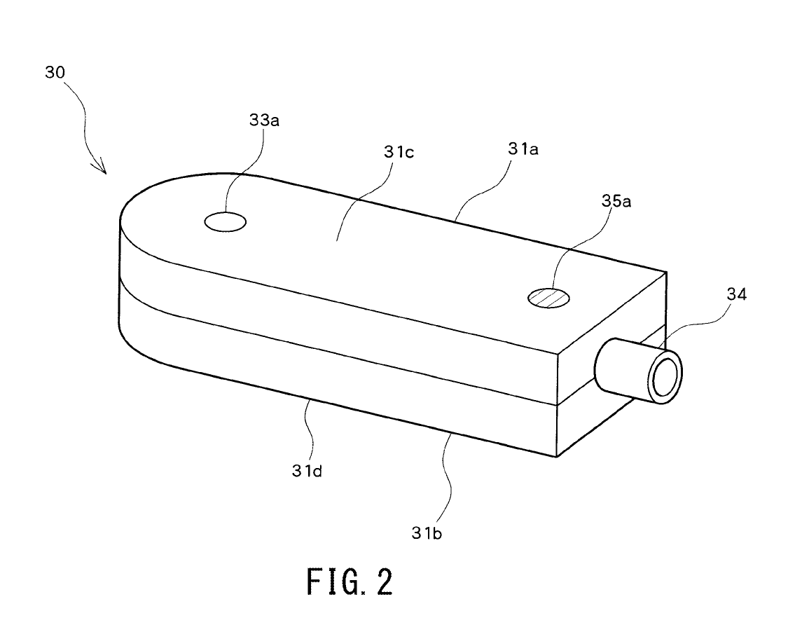

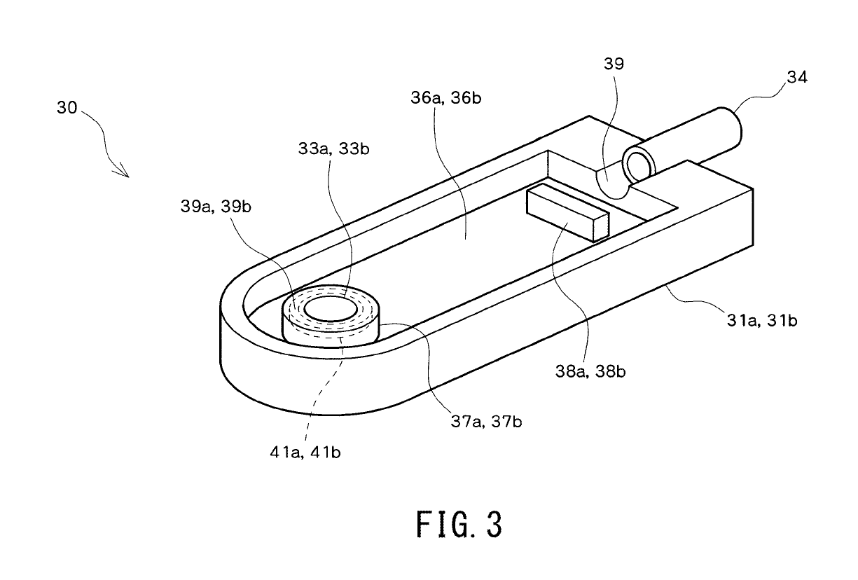

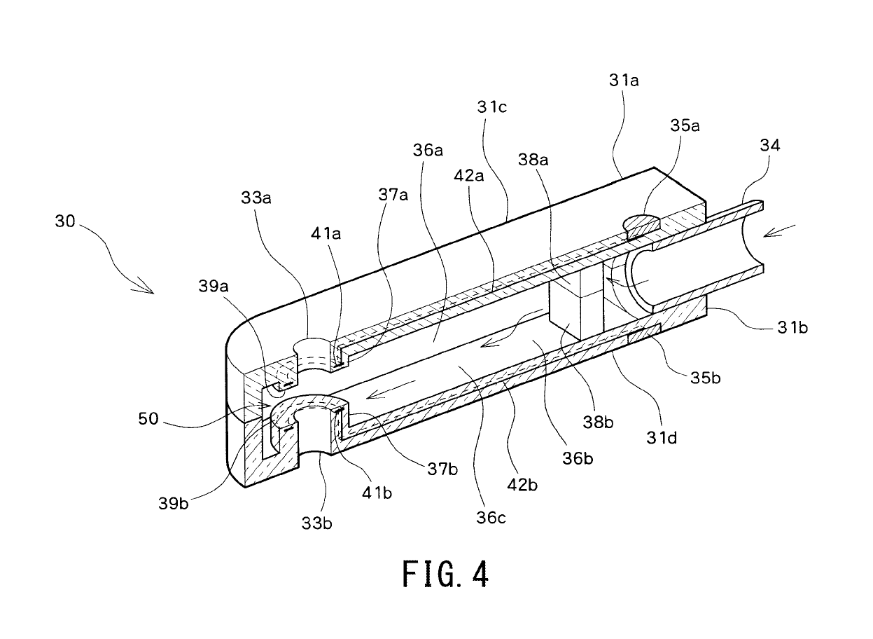

As illustrated in FIG. 2 and FIG. 3, the wire-cleaning plasma unit 30 is an assembly of an upper-half casing 31a and a lower-half casing 31b that are made of ceramics, and the holes 33a and 33b through which the wire 21 is inserted are provided in upper and lower walls 31c and 31d of the casings 31a and 31b, respectively. In addition, the casings 31a and 31b are provided respectively with electrodes 35a and 35b to which electric wires from the direct-current pulse power unit 45 are connected. As illustrated in FIG. 3, inside the casings 31a and 31b, there are respectively provided depressed portions 36a and 36b that constitute a hollow portion 36c illustrated in FIG. 4 when assembling the casings 31a and 31b. In addition, bosses 37a and 37b, in which annular plasma-generating electrodes 41a and 41b are respectively embedded, protrude around the holes 33a and 33b. Tip end surfaces 39a and 39b respectively of the bosses 37a and 37b are lower than joining surfaces of the casings 31a and 31b, and configured such that a space is provided between the tip end surfaces 39a and 39b of the bosses 37a and 37b when the casings 31a and 31b are assembled.

The casings 31a and 31b are respectively provided with depressions 39 whose section is semicircular on the side opposite of the side on which the holes 33a and 33b are provided. The depressions 39 whose section is semicircular form a cylindrical hole in which the gas inlet tube 34 is attached when the casings 31a and 31b are assembled. Further, projections 38a and 38b are disposed in the depressed portions 36a and 36b near the depressions 39 to which the gas inlet tube 34 is connected. The projections 38a and 38b are for allowing a gas enters through the gas inlet tube 34 evenly in the hollow portion 36c illustrated in FIG. 4.

A state in which the upper-half casing 31a and the lower-half casing 31b thus configured are assembled will be described with reference to FIG. 4. When the upper-half casing 31a is laid over the lower-half casing 31b are such that the depressed portions 36a and 36b face each other, the joining surfaces around the casings 31a and 31b are attached closely to each other, and the hollow portion 36c is formed inside. Further, as the tip end surfaces 39a and 39b of the bosses 37a and 37b are lower than the joining surfaces of the casings 31a and 31b, a space 50 is provided between the tip end surfaces 39a and 39b when the casings 31a and 31b are assembled. When the casings 31a and 31b are assembled, the holes 33a and 33b provided in the walls of the casings 31a and 31b are positioned so as to face each other, and the bosses 37a and 37b are respectively provided concentrically with the holes 33a and 33b. Therefore, the tip end surfaces 39a and 39b of the bosses 37a and 37b are also positioned facing each other.

The height of the projections 38a and 38b is substantially the same as that of the joining surfaces of the casings 31a and 31b. When the casings 31a and 31b are assembled, their tip end surfaces are closely attached to each other, the gas entering through the gas inlet tube 34 is allowed to flow into the hollow portion 36c by both sides of the projections 38a and 38b as shown by arrows in FIG. 4, and the gas flow within the hollow portion 36c is uniformized.

As illustrated in FIG. 4, the electrodes 35a and 35b embedded in the walls 31c and 31d of the casings 31a and 31b are partially exposed from surfaces of the walls 31c and 31d of the casings 31a and 31b. Further, between the electrodes 35a and 35b and the respective plasma-generating electrodes 41a and 41b embedded in the bosses 37a and 37b are connected by connecting wires 42a and 42b embedded in the walls 31c and 31d.

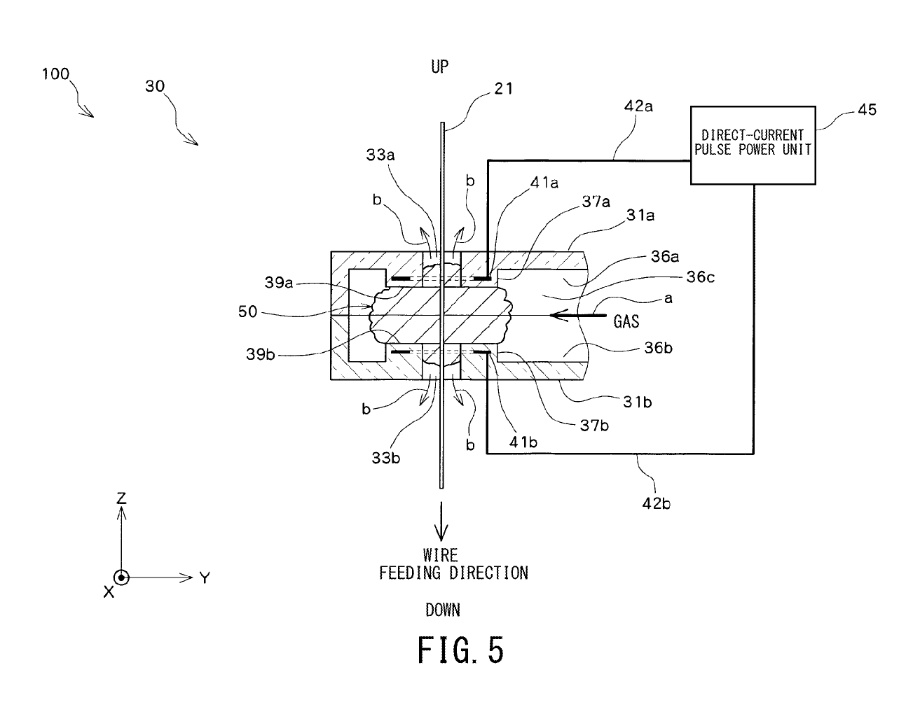

An operation of the wire-cleaning plasma unit 30 thus configured will be described with reference to FIG. 5. As illustrated in FIG. 1, the wire-cleaning plasma unit 30 is fixed to the upper frame 11a, and the wire 21 penetrates through the holes 33a and 33b and extends downward. As indicated by an arrow a in FIG. 5, a gas for generating plasma flows from the gas inlet tube 34 illustrated in FIG. 1 into the hollow portion 36c. The gas is an inert gas such as nitrogen or argon. Further, the plasma-generating electrodes 41a and 41b are connected to the direct-current pulse power unit 45 via the connecting wires 42a and 42b. First, before current is applied to the plasma-generating electrodes 41a and 41b, the gas flows from the hollow portion 36c around the bosses 37a and 37b and then horizontally along outer circumferences of the tip end surfaces 39a and 39b of the bosses 37a and 37b into the holes 33a and 33b inside, and then flows upward and downward out through the holes 33a and 33b. Accordingly, the pressure within the hollow portion 36c is slightly higher than the atmospheric pressure. Therefore, air is not enter the hollow portion 36c through the holes 33a and 33b, and the hollow portion 36c of the wire-cleaning plasma unit 30 is filled with an inert gas and maintained to be an inert gas atmosphere.

Then, when direct-current pulse power supplied from the direct-current pulse power unit 45 is applied to the plasma-generating electrodes 41a and 41b, plasma is generated in the space 50 between the tip end surfaces 39a and 39b of the bosses 37a and 37b. The plasma is generated between the annular plasma-generating electrodes 41a and 41b, and then flows toward the central portions of the holes 33a and 33b along with a flow of the inert gas, and then flows upward and downward through the holes 33a and 33b. The plasma generated here is brought into contact with the surface of the wire 21 extending vertically through the holes 33a and 33b within the space 50 and the holes 33a and 33b, and removes foreign matters such as organic impurities on the surface of the wire. Life duration of the plasma generated between the plasma-generating electrodes 41a and 41b is very short, and the plasma disappears after the generation before it flows outside through the holes 33a and 33b and returns to the original inert gas. Then, as indicated by arrows b in FIG. 5, the inert gas restored from the plasma is discharged outside through the holes 33a and 33b.

As described above, the wire-cleaning plasma unit 30 according to this embodiment generates plasma in the space 50 within the casings 31a and 31b in the state in which air can not enter, and therefore the generated plasma cannot become oxidized. Therefore, it is possible to clean the surface of the wire 21 without causing oxidation of the surface of the wire 21. Accordingly, it is possible to effectively clean the surface of the wire 21 with a simple apparatus without providing a compensating device or the like as described in PTL 1 that suppresses oxidation of the wire surface by blowing a reducing or noble gas to the wire after organic impurities attached to the wire surface have been removed by plasma.

The above embodiment describes that the wire-cleaning plasma unit 30 is disposed between the two wire-feed guides 17 and 18, and the wire 21 between the wire-feed guides 17 and 18 penetrate through the holes 33a and 33b. However, the wire-cleaning plasma unit 30 not be necessarily disposed between the wire-feed guides 17 and 18 as long as being attached to the upper frame 11a fixed to the base 11.

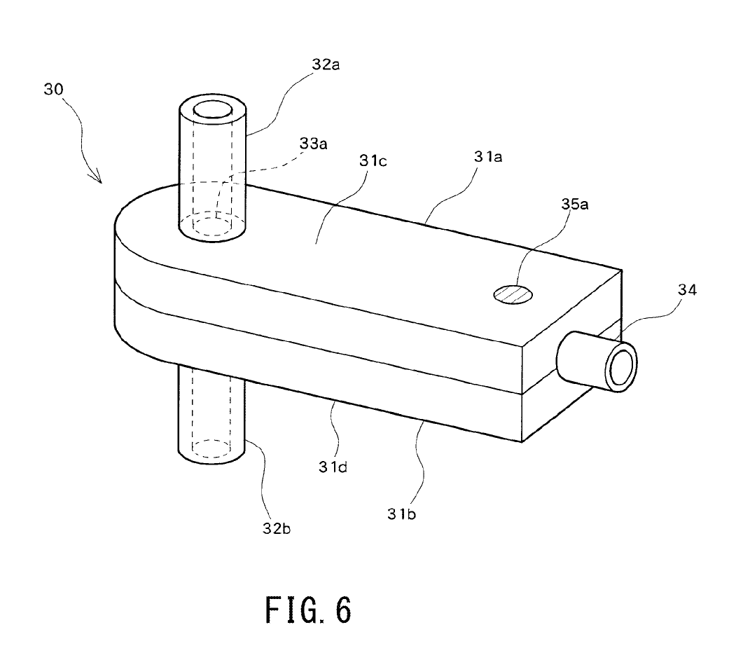

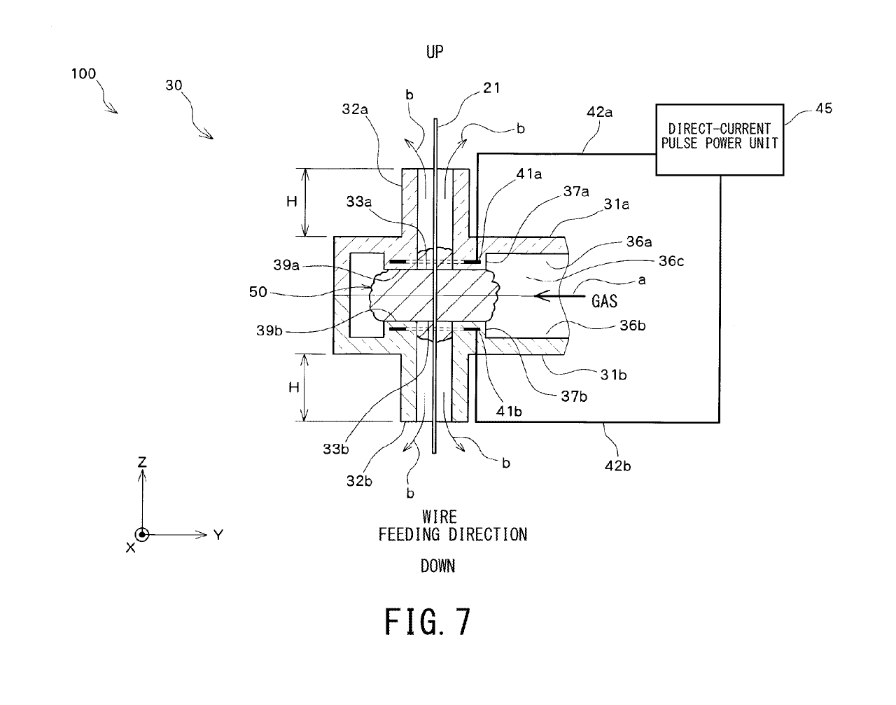

Next, another embodiment of the present invention will be described with reference to FIG. 6 and FIG. 7. Like components as those in the embodiment described with reference to FIG. 1 through FIG. 5 are denoted by like reference numerals, and their descriptions shall be omitted. As illustrated in FIG. 6, in this embodiment, pipes 32a and 32b through which the wire 21 is inserted and that communicate with the holes 33a and 33b provided in the upper-half casing 31a and the lower-half casing 31b, respectively, are attached to outer surfaces of the walls 31c and 31d of the casings 31a and 31b.

For example, depending on how the wire 21 is dirty, there is a case in which it is necessary to use more powerful plasma to clean the wire 21. In such a case, the temperature of the generated plasma increases. According to the wire-cleaning plasma unit 30 of the embodiment described with reference to FIG. 1 through FIG. 5, the temperature of the inert gas that flows from the holes 33a and 33b becomes high, and the cleaned wire 21 that is fed downward through the lower hole 33b is brought into contact with air outside the hole 33b in a state its surface temperature is high. At this time, there is a case in which the surface is oxidized due to oxygen contained in the air depending on the surface temperature of the wire 21, and bonding qualities can decrease.

Thus, according to this embodiment, as illustrated in FIG. 7, by providing the pipes 32a and 32b, the plasma generated between the plasma-generating electrodes 41a and 41b is cooled from outer surfaces of the pipes 32a and 32b while flowing through the pipes 32a and 32b after restored to the inert gas in the holes 33a and 33b. Accordingly, the temperature of the wire 21 inserted through the pipes 32a and 32b is also reduced down to the temperature at which the surface of the wire is not oxidized when the wire 21 comes out of the pipes 32a and 32b. With this, even when the wire 21 is cleaned using high-temperature plasma depending on how the wire 21 is dirty, it is possible to feed the cleaned wire 21 to the capillary 15 without making the surface of the cleaned wire 21 be oxidized, and to improve bonding qualities.

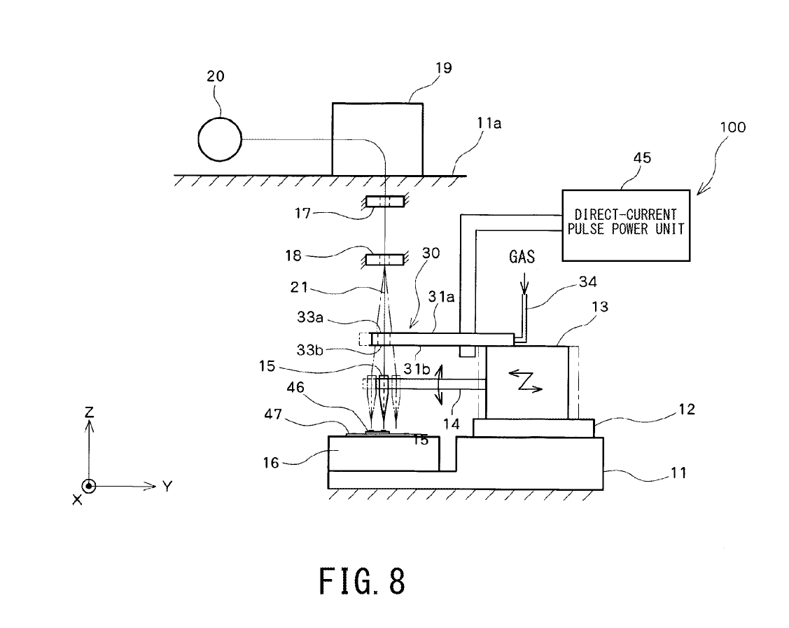

The above embodiments describe that the wire-cleaning plasma unit 30 is attached to the upper frame 11a fixed to the base 11. However, the wire-cleaning plasma unit 30 can be attached to the bonding head 13 as illustrated in FIG. 8. In this case, cleaning of the wire 21 is performed at a position closer to the capillary 15, and therefore it is possible to more effectively clean the wire 21. Further, when the wire-cleaning plasma unit 30 is attached to the bonding head 13 in this manner, the holes 33a and 33b can have the size so as to absorb swing of the wire 21 as the bonding head 13 moves in the X and Y directions as illustrated in FIG. 8.

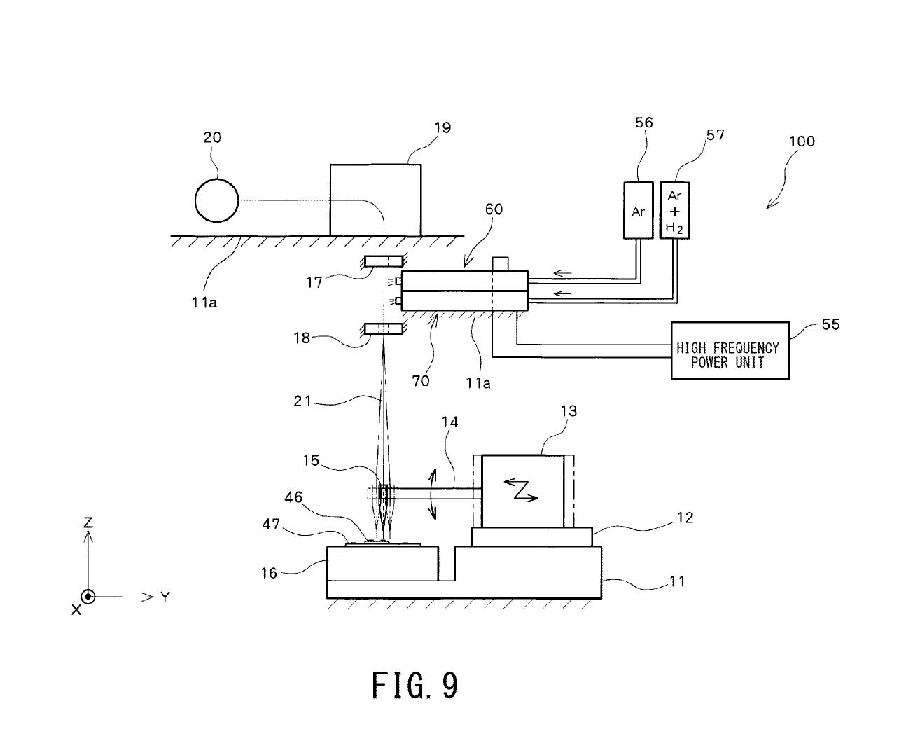

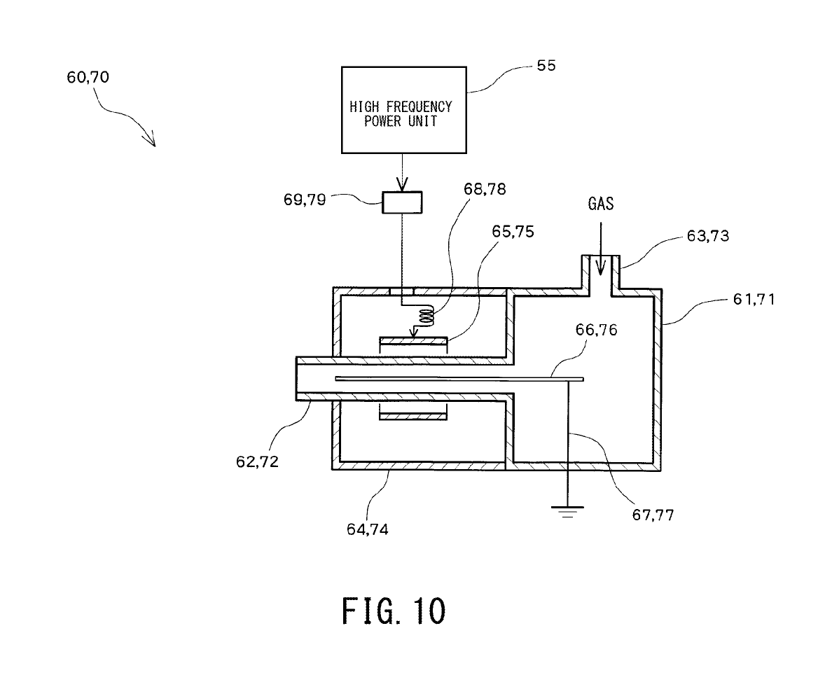

Yet another embodiment of the present invention will be described with reference to FIG. 9 and FIG. 10. Like components as those in the embodiment described with reference to FIG. 1 through FIG. 8 are denoted by like reference numerals, and their descriptions shall be omitted. As illustrated in FIG. 9, this embodiment is provided with, in place of the wire-cleaning plasma unit 30 of the embodiment described with reference to FIG. 1, a cleaning plasma unit 60 configured to blow plasma jet for cleaning toward the wire 21 between the wire-feed guides 17 and 18, and a reducing plasma unit 70 disposed on the side of the capillary from the cleaning plasma unit 60 and configured to further blow plasma for reducing to the wire 21 between the wire-feed guides 17 and 18 after the cleaner plasma has been blown. As illustrated in FIG. 9, the cleaning plasma unit 60 is supplied with an inert gas of argon as a gas for cleaner plasma, and the reducing plasma unit 70 is supplied with a mixed gas of argon and hydrogen as a gas for reduction plasma.

As illustrated in FIG. 10, each of the plasma units 60 and 70 includes a corresponding one of chambers 61 and 71 to which a corresponding one of gas inlets 63 and 73 through which an argon gas supplied from an argon gas tank 56 as the gas for cleaner plasma or a mixed gas of argon and hydrogen supplied from the mixed gas tank 57 as the gas for reduction plasma are introduced is attached, a corresponding one of cylindrical plasma nozzles 62 and 72 extending from the corresponding one of the chambers 61 and 71, a corresponding one of central electrodes 66 and 76 disposed in the center of the corresponding one of the plasma nozzles 62 and 72, a corresponding one of cylindrical external electrodes 65 and 75 disposed outside the corresponding one of the plasma nozzles 62 and 72, and a corresponding one of casings 64 and 74 that covers outside the corresponding one of the external electrodes 65 and 75. The central electrodes 66 and 76 are grounded via grounding wires 67 and 77, respectively, and either of the external electrodes 65 and 75 is connected to a high frequency power unit 55 via a corresponding one of coils 68 and 78 and a corresponding one of matching devices 69 and 79.

The argon gas or the mixed gas introduced into the chamber 61 or 71 through the gas inlet 63 or 73 is turned into plasma for cleaning or plasma for reducing by high frequency electric power applied between the central electrode 66 or 76 and the external electrode 65 or 75, and jetted from a tip end of the plasma nozzle 62 or 72.

As illustrated in FIG. 9, the cleaning plasma unit 60 jets the plasma for cleaning toward the wire 21, to remove foreign matters such as organic substances attached to the surface of the wire 21. The cleaning plasma unit 60 produces oxidation plasma as the plasma gas for cleaning is plasmatized in an open state to atmosphere. Accordingly, while it is possible to effectively remove foreign matters from the surface of the wire 21, the surface of the wire 21 is oxidized. After the wire 21 is blown by plasma for cleaning by the cleaning plasma unit 60, the wire 21 is fed downward and then blown by plasma for reducing by the reducing plasma unit 70. The plasma for reducing is produced by plasmatizing a mixed gas of argon and hydrogen, and has an effect of reducing the surface of the wire 21. Therefore, when the plasma for reducing is jetted, an oxidized film or an oxidative product over the surface of the wire 21 is removed, and the wire 21 with a cleaned surface is fed the capillary 15. As described above, according to this embodiment, as reduction is performed after removing foreign matters from the surface of the wire 21, the surface of the wire 21 can be cleaned without any foreign matters, oxidation film, or oxidative products, and thus it is possible to improve bonding qualities.

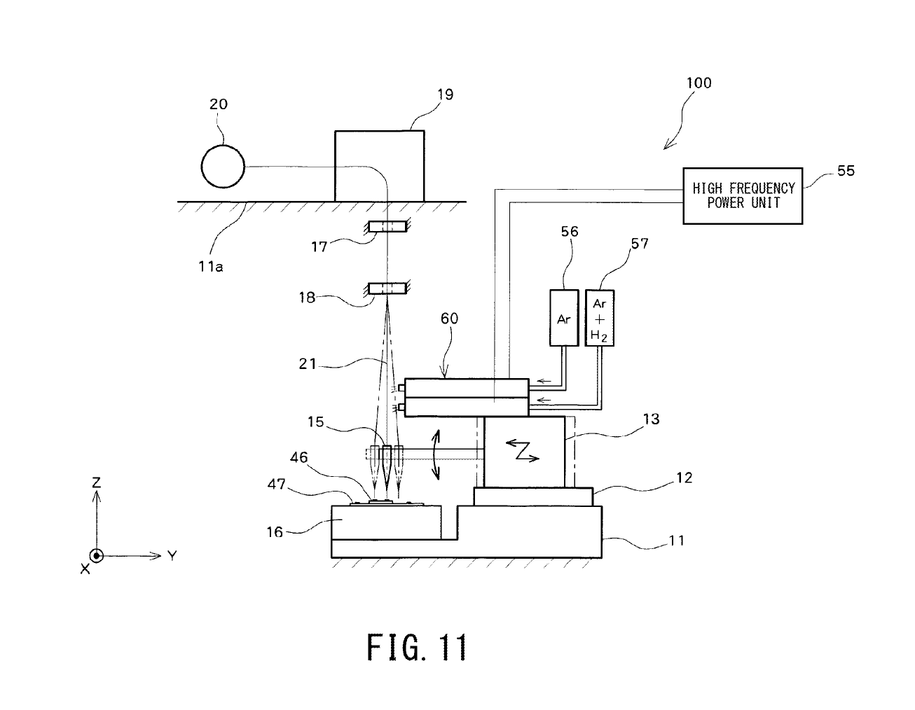

Further another embodiment of the present invention will be described with reference to FIG. 11. In this embodiment, the cleaning plasma unit 60 and the reducing plasma unit 70 in the embodiment described with reference to FIG. 9 are attached to the bonding head 13. This embodiment provides the same effect as that previously described with reference to FIG. 9.

The present invention is not limited to the embodiments described above, and includes any modifications and alterations without departing from the technical scope and the spirit of the present invention defined by the appended claims.

### REFERENCE SIGNS LIST

11: Base
11a: Upper Frame
12: XY Table
13: Bonding Head
14: Bonding Arm
15: Capillary
16: Bonding Stage
17, 18: Wire-Feed Guide
19: Air Guide
20: Wire Spool
21: Wire
30: Wire-Cleaning Plasma Unit
31a: Upper-Half Casing
31b: Lower-Half Casing
31c, 31d: Wall
32a, 32b: Pipe
33a, 33b: Hole
34: Gas Inlet Tube
35a, 35b: Electrode
36a, 36b: Depressed Portion
36c: Hollow Portion
37a, 37b: Boss
38a, 38b: Projection
39: Depression
39a, 39b: Tip End Surface
41a, 41b: Plasma-Generating Electrode
42a, 42b: Connecting Wire
45: Direct-Current Pulse Power Unit
46: Semiconductor Die
47: Substrate
50: Space
55: High Frequency Power Unit
56: Argon Gas Tank
57: Mixed Gas Tank
60: Cleaning Plasma Unit
61, 71: Chamber
62, 72: Plasma Nozzle
63, 73: Gas Inlet
64, 74: Casing
65, 75: External Electrode
66, 76: Central Electrode
67, 77: Grounding Wire
68, 78: Coil
69, 79: Matching Device
70: Reducing Plasma Unit
100: Wire Bonding Apparatus

1. A wire bonding apparatus, comprising:
a base body;
a bonding head configured to move a bonding tool in X, Y, and Z directions with respect to the base body;
a wire spool attached to the base body, and configured to feed a wire to the bonding tool; and
a wire-cleaning plasma unit disposed between the wire spool and the bonding tool, wherein
the wire-cleaning plasma unit comprises:
hollow casings in which an inert gas is introduced, so that an internal pressure is higher than an atmospheric pressure;
holes respectively provided in walls of the casings, and face against each other, so that the wire is inserted therebetween; and
electrodes respectively disposed within the walls of the casings around circumferences of the holes, so as to face against each other the holes, and wherein
the wire is cleaned by applying current to the electrodes and having the wire be inserted into plasma in a space between the electrodes within the casings generated in a state in which air is not contained.

2. The wire bonding apparatus according to claim 1, wherein
the wire-cleaning plasma unit is attached to the bonding head.

3. The wire bonding apparatus according to claim 1, further comprising:
at least two wire-feed guides attached to the base body, and configured to guide the wire fed from the wire spool in a linear direction, wherein
the wire-cleaning plasma unit is attached to the base body between the wire-feed guides.

4. The wire bonding apparatus according to claim 1, wherein
the casings respectively comprise pipes on outer surfaces of the walls, each pipe being communicated with a corresponding one of the holes and allowing the wire to be inserted therethrough.

5. The wire bonding apparatus according to claim 2, wherein
the casings respectively comprise pipes on outer surfaces of the walls, each pipe being communicated with a corresponding one of the holes and allowing the wire to be inserted therethrough.

6. The wire bonding apparatus according to claim 3, wherein
the casings respectively comprise pipes on outer surfaces of the walls, each pipe being communicated with a corresponding one of the holes and allowing the wire to be inserted therethrough.

7. A wire bonding apparatus, comprising:
a base body;
a bonding head configured to move a bonding tool in X, Y, and Z directions with respect to the base body;
a wire spool attached to the base body, and configured to feed a wire to the bonding tool;
at least two wire-feed guides attached to the base body, and configured to guide the wire fed from the wire spool in a linear direction; and
a cleaning plasma unit configured to blow plasma jet for cleaning to the wire between the wire-feed guides.

8. The wire bonding apparatus according to claim 7, further comprising a reducing plasma unit disposed on the side of the bonding tool from the cleaning plasma unit, and configured to further blow plasma for reducing to the wire between the wire-feed guides after the plasma for cleaning has been blown.

9. A wire bonding apparatus, comprising:
a base body;
a bonding head configured to move a bonding tool in X, Y, and Z directions with respect to the base body;
a wire spool attached to the base body, and configured to feed a wire to the bonding tool; and
a cleaning plasma unit attached to the bonding head, and configured to blow plasma jet for cleaning to the wire.

10. The wire bonding apparatus according to claim 9, further comprising a reducing plasma unit attached to the bonding head on the side of the bonding tool from the cleaning plasma unit, and configured to further blow plasma for reducing to the wire after the plasma for cleaning has been blown.
